(19) United States
(12) Patent Application Publication
(10) Pub. No.: US 2024/0276706 A1
(43) Pub. Date: Aug. 15, 2024

(54) SEMICONDUCTOR DEVICE AND MANUFACTURING METHOD THEREOF

(71) Applicant: Winbond Electronics Corp., Taichung City (TW)

(72) Inventor: Hung-Yu Wei, Taichung City (TW)

(73) Assignee: Winbond Electronics Corp., Taichung City (TW)

(21) Appl. No.: 18/167,905

(22) Filed: Feb. 13, 2023

(51) Int. Cl. H10B 12/00

(52) U.S. Cl. CPC H10B 12/33; H01L 28/88; H01L 28/92; H10B 12/0385

(57) ABSTRACT

Provided are a semiconductor device and a manufacturing method thereof. The semiconductor device includes a substrate, a capacitor, a patterned conductive layer and a contact.

The substrate includes an array region and a peripheral region. A transistor is disposed in the substrate in the array region. A conductive device is disposed in the substrate in the peripheral region. The capacitor is disposed on the substrate and electrically connected to the transistor. The patterned conductive layer is disposed on the capacitor and includes a pattern portion and a connection portion connected to the pattern portion. The pattern portion is located in the array region and exposes a part of the capacitor, and the connection portion is extended into the peripheral region. The contact is disposed on the substrate in the peripheral region and connects the connection portion and the conductive device.

### BACKGROUND

### Technical Field

The present invention relates to a semiconductor device and a manufacturing method thereof, and in particular to a semiconductor device with a capacitor and a manufacturing method thereof.

### Description of Related Art

In a process of a semiconductor device, a H₂ sintering process is performed to repair the dangling bonds formed in the substrate to improve the electrical performance of the semiconductor device. In the dynamic random access memory (DRAM), when the H₂ sintering process is performed, the upper electrode of the capacitor may be acted as a barrier when hydrogen is entered into the silicon substrate from the outside, and thus the H2 sintering process is hindered. As a result, the electrical performance of the semiconductor device cannot be effectively improved.

### SUMMARY

The present invention provides a semiconductor device and a manufacturing method thereof, which may effectively avoid the capacitance drop of the capacitor under a high-frequency operation, and may improve the electrical performance of the semiconductor device.

The semiconductor device of present invention includes a substrate, a capacitor, a patterned conductive layer and a contact. The substrate includes an array region and a peripheral region. A transistor is disposed in the substrate in the array region. A conductive device is disposed in the substrate in the peripheral region. The capacitor is disposed on the substrate and electrically connected to the transistor. The patterned conductive layer is disposed on the capacitor and includes a pattern portion and a connection portion connected to the pattern portion. The pattern portion is located in the array region and exposes a part of the capacitor, and the connection portion is extended into the peripheral region. The contact is disposed on the substrate in the peripheral region and connects the connection portion and the conductive device.

The manufacturing method of a semiconductor device of the present invention includes the following steps. A substrate is provided, wherein the substrate comprises an array region and a peripheral region, a transistor is formed in the substrate in the array region, and a conductive device is formed in the substrate in the peripheral region. A capacitor is formed on the substrate in the array region, wherein the capacitor is electrically connected to the transistor. A contact is formed on the substrate in the peripheral region, wherein the contact is connected to the conductive device. A patterned conductive layer is formed on the capacitor, wherein the patterned conductive layer comprises a pattern portion and a connection portion connected to the pattern portion, the pattern portion is located in the array region and exposes a part of the capacitor, and the connection portion is extended into the peripheral region to connect to the contact.

Based on the above, in the semiconductor device of the present invention, the patterned conductive layer including the pattern portion and the connection portion connected to the pattern portion is formed on the capacitor, and the pattern portion exposes a part of the capacitor. In this way, during the H₂ sintering process, the hydrogen gas may pass through the gaps between the metal components from the outside and enter into the substrate through the regions not covered by the patterned conductive layer, so as to repair the dangling bonds in the substrate, thereby improving the electrical performance of the semiconductor device.

In addition, in the semiconductor device of the present invention, since the pattern portion of the patterned conductive layer has a roughly uniform width from the top surface to the bottom surface, compared with the general contact in which the top width is greater than the bottom width, the pattern portion of the patterned conductive layer may be have a lower resistance value. In this way, the capacitance drop of the capacitor under high-frequency operation may be effectively avoided.

Further, in the manufacturing method of the semiconductor device of the present invention, in the formed patterned conductive layer, the pattern portion may be used as the contact electrically connected to the capacitor, and the connection portion may be used as the circuit layer electrically connected to the contact located in the peripheral region. In this way, the process steps may be effectively simplified.

### BRIEF DESCRIPTION OF THE DRAWINGS

FIGS. 1A to 1C are schematic cross-sectional views of the manufacturing process of the semiconductor device of the first embodiment of the present invention.

FIG. 2 is a schematic perspective view of the semiconductor device of the first embodiment of the present invention.

FIGS. 3A to 3B are schematic cross-sectional views of the manufacturing process of the semiconductor device of the second embodiment of the present invention.

FIGS. 4A to 4C are schematic cross-sectional views of the manufacturing process of the semiconductor device of the third embodiment of the present invention.

FIG. 5 is a schematic perspective view of the semiconductor device of the third embodiment of the present invention.

FIGS. 6A to 6C are schematic top views of the patterned conductive layers in different embodiments of the present invention.

### DESCRIPTION OF THE EMBODIMENTS

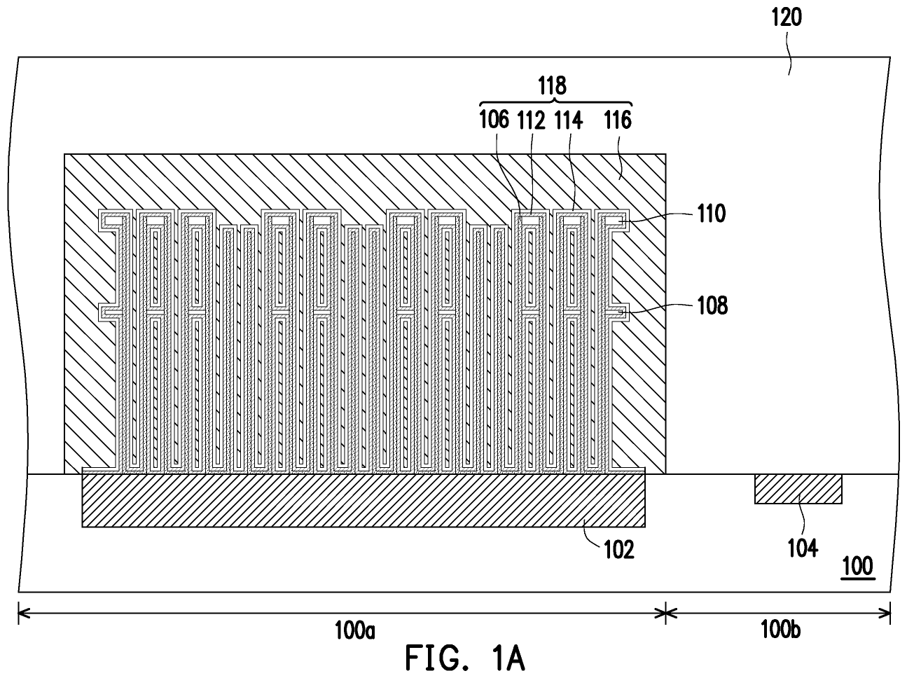

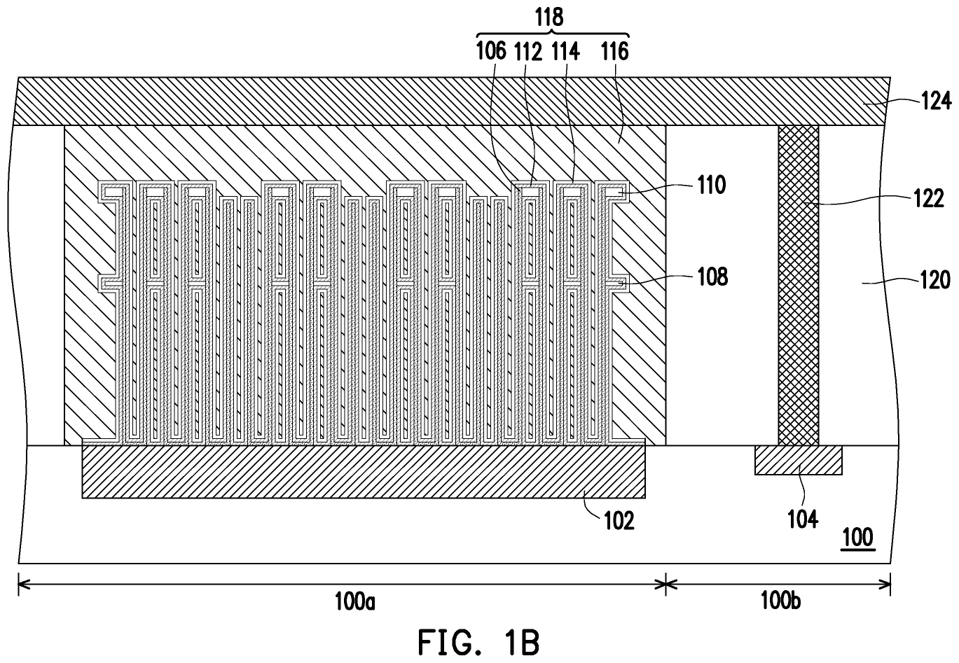

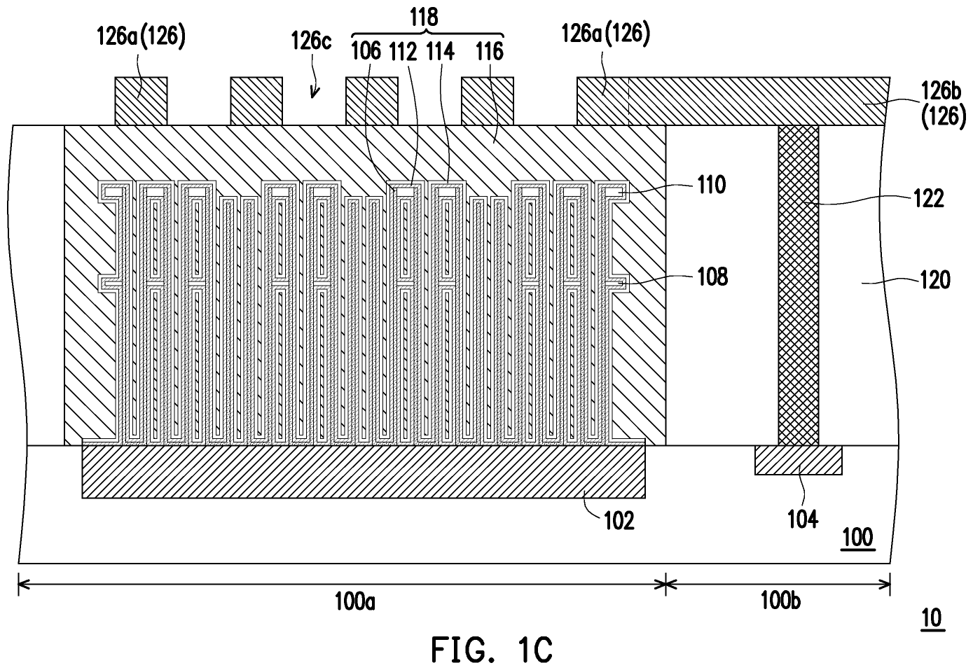

Referring to FIG. 1A, a substrate 100 is provided. In the present embodiment, the substrate 100 includes an array region 100a and a peripheral region 100b. In the present embodiment, the substrate 100 includes a silicon base and a dielectric layer formed on the silicon base, wherein the dielectric layer covers transistors, an interconnect structure, circuit patterns, and the like disposed on the silicon base. The array region 100a is a region for disposing a memory including a capacitor. For example, the dynamic random access memory may be formed after the capacitor and the transistor on the silicon substrate are electrically connected. The peripheral region 100b is a region for disposing the interconnect structure, circuit patterns, and the like. The detailed architecture of the substrate 100 is well known to a person skilled in the art and will not be further described here.

In the present embodiment, an electron device region 102 located in the substrate 100 in the array region 100a may include the above-mentioned transistors, interconnect structure, etc., and a conductive device region 104 located in the substrate 100 in the peripheral region 100b may include the above-mentioned interconnect structure, circuit patterns, and the like.

Next, a plurality of hollow cylinder first electrodes 106 are formed on the substrate 100 in the array region 100a. The first electrodes 106 are electrically connected to the corresponding transistors in the electron device region 102. The material of the first electrode 106 is, for example, titanium, titanium nitride or a combination thereof. In the present embodiment, after the first electrodes 106 are formed, a dielectric layer 108 and a dielectric layer 110 are remained between adjacent first electrodes 106 to stabilize the first electrodes 106, but the present invention is not limited thereto. The material of the dielectric layer 108 and the dielectric layer 110 is, for example, silicon nitride. Then, a insulating layer 112 may be formed conformally on the first electrodes 106. The material of the insulating layer 112 is, for example, a high-k material. Next, a conductive layer 114 may be formed conformally on the insulating layer 112, but the present invention is not limited thereto. The material of the conductive layer 114 is, for example, titanium, titanium nitride or a combination thereof. Afterwards, a second electrode 116 may be formed on the conductive layer 114. The material of the second electrode 116 is, for example, a doped semiconductor material. For example, the material of the second electrode 116 may be boron-doped silicon germanium (BSiGe) or doped polysilicon.

In the present embodiment, the first electrodes 106, the insulating layer 112, the conductive layer 114 and the second electrode 116 may form a capacitor 118, wherein the first electrodes 106 are used as the lower electrode, the insulating layer 112 is used as the capacitor dielectric layer, and the conductive layer 114 and the second electrode 116 are used as the upper electrode. In addition, in the present embodiment, the capacitor 118 is a cylinder capacitor, but the present invention is not limited thereto.

Next, a first dielectric layer 120 is formed on the substrate 100 to cover the capacitor 118 and various components exposed at the surface of the substrate 100. In the present embodiment, the first dielectric layer 120 is a silicon oxide layer, but the present invention is not limited thereto.

Referring to FIG. 1B, a chemical mechanical polishing (CMP) process is performed to remove a part of the first dielectric layer 120 until the top surface of the capacitor 118 is exposed. In the present embodiment, after the chemical mechanical polishing process, the top surface of the upper electrode (second electrode 116) of the capacitor 118 is exposed. Next, a contact 122 connected to the conductive device region 104 is formed in the first dielectric layer 120 in the peripheral region 100b. A method for forming the contact 122 may include the following steps. After the chemical mechanical polishing process, a hole exposing a part of the conductive device region 104 is formed in the first dielectric layer 120 in the peripheral region 100b. After that, the hole is filled with a conductive material. Thus, in the present embodiment, the top surface of the capacitor 118 (the top surface of the second electrode 116), the top surface of the first dielectric layer 120 and the top surface of the contact 122 are substantially coplanar. That is, the top surface of the capacitor 118 (the top surface of the second electrode 116), the top surface of the first dielectric layer 120 and the top surface of the contact 122 are substantially located at the same level.

After that, a conductive material layer 124 is formed on the upper electrode (second electrode 116) of the capacitor 118, the first dielectric layer 120 and the contact 122. The conductive material layer 124 is, for example, a metal layer made of copper, aluminum or tungsten, but the present invention is not limited thereto. The conductive material layer 124 is used as a material layer for contacts and a circuit pattern formed later, wherein the contacts may be connected to the upper electrode (second electrode 116) of the capacitor 118, and the circuit pattern may be connected to the contact 122. In other embodiments, a barrier layer may be formed above and/or below the conductive material layer 124. For example, when the material of the conductive material layer 124 is aluminum or tungsten, the barrier layer may be a composite layer composed of a titanium layer and a titanium nitride layer. In addition, when the material of the conductive material layer 124 is copper, the barrier layer may be a tantalum layer.

Referring to FIG. 1C, a patterning process is performed on the conductive material layer 124 to form a patterned conductive layer 126. In this way, a semiconductor device 10 of the present embodiment may be completed.

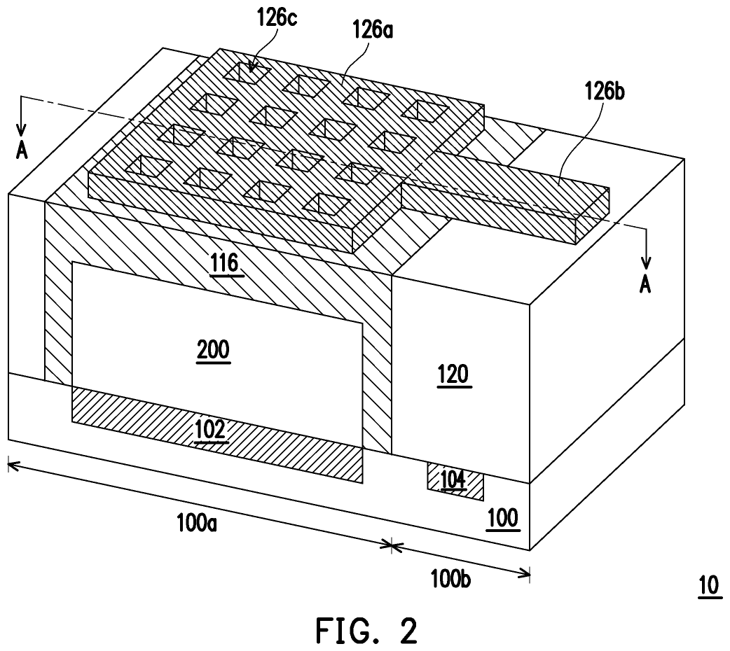

FIG. 2 is a schematic perspective view of the semiconductor device 10 of the present embodiment, wherein FIG. 1C is a schematic cross-sectional view along the line A-A in FIG. 2. In addition, in order to make the drawing clear, in FIG. 2, a region 200 includes the first electrodes 106, the dielectric layer 108, the dielectric layer 110, the insulating layer 112 and the conductive layer 114, and the detailed structures thereof are not shown.

Referring to FIGS. 1C and 2 at the same time, in the present embodiment, the patterned conductive layer 126 includes a pattern portion 126a and a connection portion 126b connected to the pattern portion 126a. The pattern portion 126a is located in the array region 100a and has openings 126c exposing a part of the upper electrode (second electrode 116) of the capacitor 118. The connection portion 126b is connected to the pattern portion 126a in the array region 100a and extended to the peripheral region 100b to connect to the contact 122, but the present invention is not limited thereto. In other embodiments, the connection portion 126b may be connected to the pattern portion 126a at the boundary between the array region 100a and the peripheral region 100b. Alternatively, in other embodiments, the pattern portion 126a is extended into the peripheral region 100b to connect to the connection portion 126b, so that the connection portion 126b may only be located in the peripheral region 100b.

After the semiconductor device 10 is formed, the H₂ sintering process may be performed to repair the dangling bonds in the substrate 100, thereby improving the electrical performance of the semiconductor device 10. For example, in some embodiments, the H₂ sintering process may be performed after the back-end-of-line (BEOL).

In the present embodiment, since the pattern portion 126a of the patterned conductive layer 126 formed on the capacitor 118 has the openings 126c, during the H₂ sintering process, hydrogen gas may enter into the substrate 100 through the openings 126c from the outside down through the gaps between the metal components to repair the dangling bonds. In addition, since the material of the upper electrode (second electrode 116) of the capacitor 118 is not a metal material, it may not generate a barrier for hydrogen.

In addition, the patterned conductive layer 126 may be used as contacts and circuit patterns during the BEOL. In detail, in the structure formed by the BEOL, the pattern portion 126a may be used as contacts electrically connected to the capacitor 118, and the connection portion 126b may be used as a circuit layer electrically connected to the contact 122. In this way, the process steps may be effectively simplified. In addition, since the pattern portion 126a has a substantially uniform width from the top surface to the bottom surface, the pattern portion 126a may have a lower resistance value than a general contact in which the top width is greater than the bottom width. In this way, the capacitance drop of the capacitor under a high-frequency operation may be effectively avoided.

In addition, in the present embodiment, the top surface of the capacitor 118 (the top surface of the second electrode 116) and the top surface of the first dielectric layer 120 are substantially at the same level, so the length of the contact 122 located in the first dielectric layer 120 does not need to be too long to be connected to the connection portion 126b as the circuit layer. In this way, the resistance value of the contact 122 may be effectively reduced.

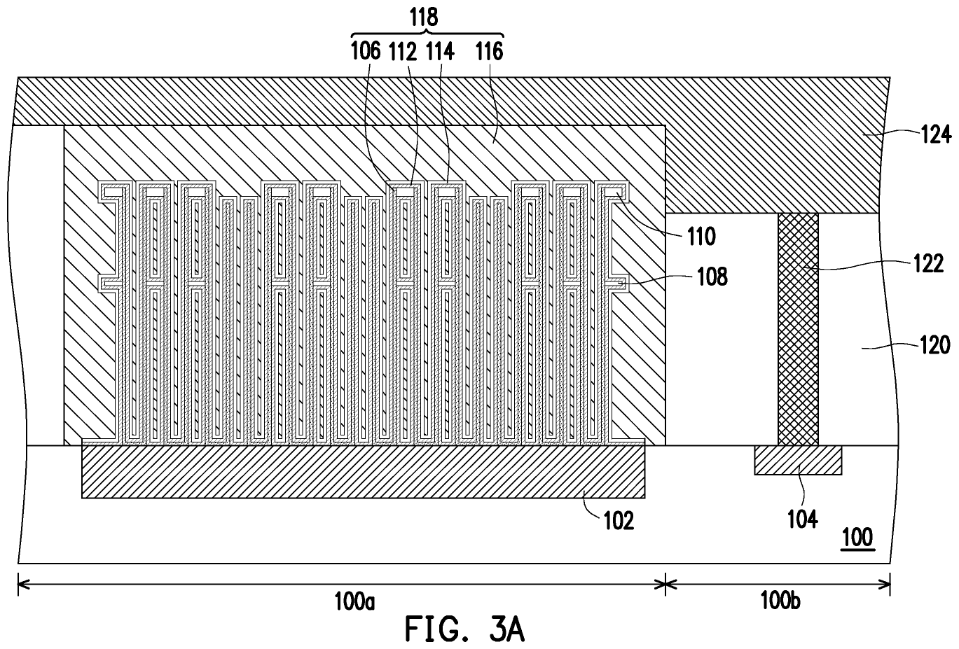

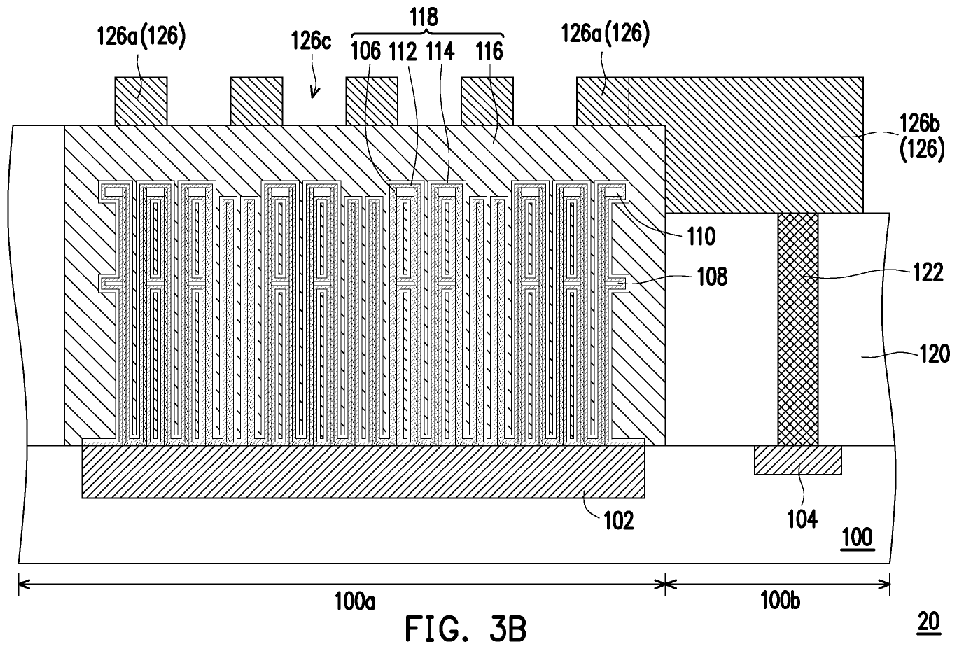

For the second embodiment of the present invention, please refer to FIGS. 3A to 3B, the same components as the first embodiment will be represented by the same reference symbols, and will not be described.

Referring to FIG. 3A, as shown in FIG. 1B, after the chemical mechanical polishing process, an etching-back process is performed on the first dielectric layer 120 to further remove a part of the first dielectric layer 120 so that the top surface of the first dielectric layer 120 is lower than the top surface of the capacitor 118 (the top surface of the second electrode 116). Next, the contact 122 connected to the conductive device region 104 is formed in the first dielectric layer 120 in the peripheral region 100b, and therefore the top surface of the contact 122 is lower than the top surface of the capacitor 118 (the top surface of the second electrode 116). Then, the conductive material layer 124 is formed on the upper electrode (second electrode 116) of the capacitor 118, the first dielectric layer 120 and the contact 122. In the present embodiment, since the top surface of the first dielectric layer 120 is lower than the top surface of the capacitor 118 (the top surface of the second electrode 116), the bottom surface of the formed conductive material layer 124 on the first dielectric layer 120 may be lower than the top surface of the capacitor 118 (the top surface of the second electrode 116). In this way, the conductive material layer 124 on the contact 122 may have a larger thickness.

Referring to FIG. 3B, a patterning process is performed on the conductive material layer 124 to form a patterned conductive layer 126. In this way, the semiconductor device 20 of the present embodiment may be completed. As shown in FIG. 3B, the difference between the present embodiment and the first embodiment is that in the semiconductor device 20, the contact 122 has a shorter length, and the connection portion 126b on the contact 122 has a larger thickness. In this way, the contact 122 may have a lower resistance value, and the connection portion 126b as the circuit layer electrically connected to the contact 122 may also have a lower resistance value.

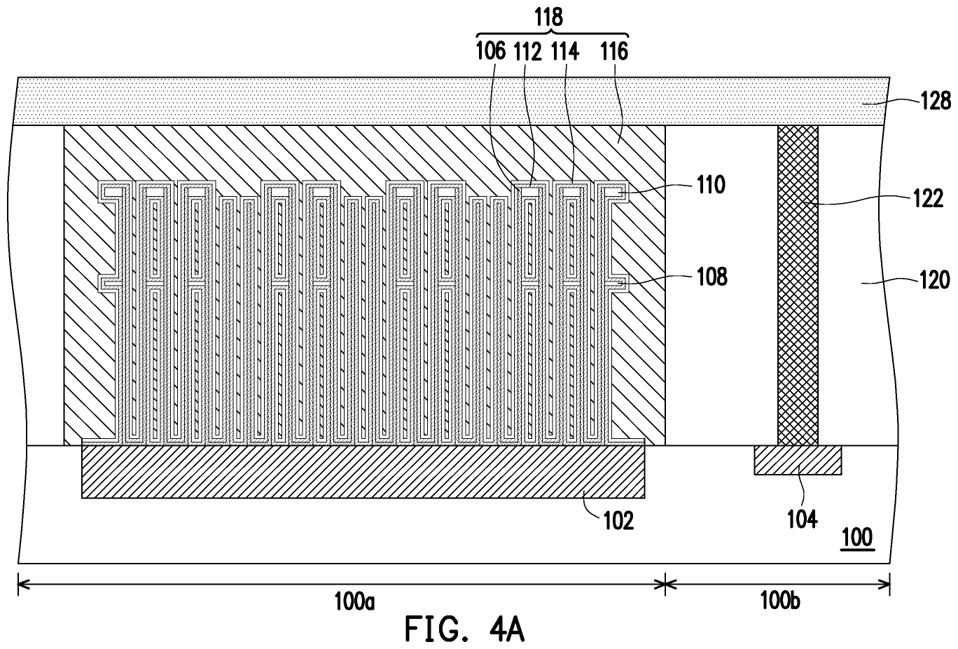

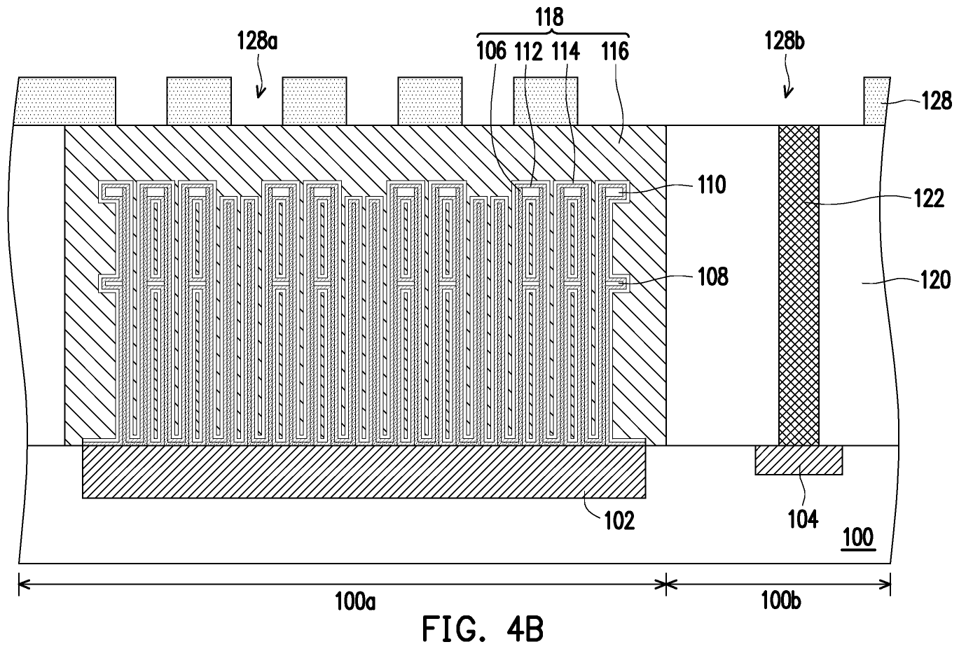

For the third embodiment of the present invention, please refer to FIGS. 4A to 4C, the same components as the first embodiment will be represented by the same reference symbols, and will not be described.

Referring to FIG. 4A, as shown in FIG. 1B, after the contact 122 is formed, a second dielectric layer 128 is formed on the upper electrode (second electrode 116) of the capacitor 118, the first dielectric layer 120 and the contact 122. A material of the second dielectric layer 128 may be the same as or different from that of the first dielectric layer 120. The second dielectric layer 128 is, for example, a silicon oxide layer, but the present invention is not limited thereto. In the present embodiment, since the top surface of the capacitor 118 (the top surface of the second electrode 116), the top surface of the first dielectric layer 120 and the top surface of the contact 122 are substantially coplanar, the formed second dielectric layer 128 may have a uniform thickness and a flat top surface.

Referring to FIG. 4B, the second dielectric layer 128 is patterned to form trenches 128a exposing a part of the upper electrode (second electrode 116) of the capacitor 118 and a trench 128b exposing the top surface of the contact 122. In the present embodiment, the positions of the trenches 128a may be corresponded to the position of the pattern portion 126a of the subsequently formed patterned conductive layer 126, and the position of the trench 128b may be corresponded to the position of the connection portion 126b of the subsequently formed patterned conductive layer 126.

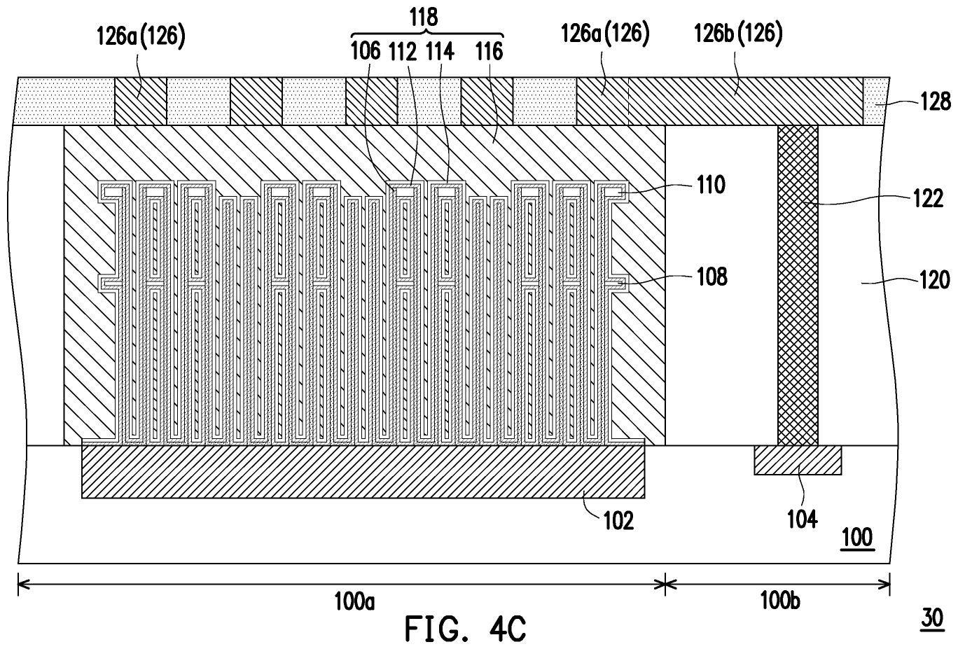

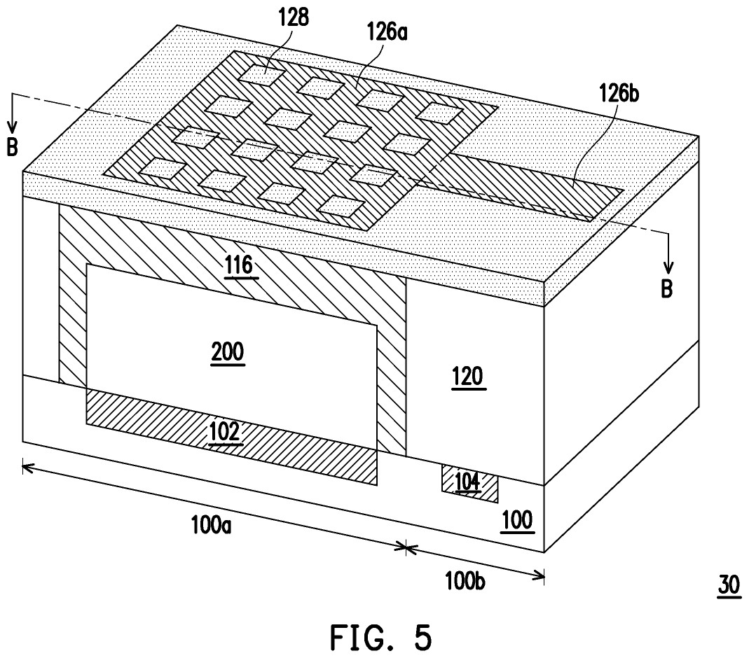

Referring to FIG. 4C, a conductive material is filled in the trenches 128a and the trench 128b to form the patterned conductive layer 126. In this way, the semiconductor device 30 of the present embodiment may be completed. In the present embodiment, the top surface of the patterned conductive layer 126 is substantially coplanar with the top surface of the second dielectric layer 128. That is, the top surface of the patterned conductive layer 126 and the top surface of the second dielectric layer 128 are substantially at the same level. FIG. 5 is a schematic perspective view of the semiconductor device 30 of the present embodiment, wherein FIG. 4C is a schematic cross-sectional view along the line B-B in FIG. 5.

In addition, similar to the second embodiment, in another embodiment, in the step as shown in FIG. 4A, before the contact 122 is formed, an etching-back process may be performed on the first dielectric layer 120 to further remove a part of the first dielectric layer 120 so that the top surface of the first dielectric layer 120 is lower than the top surface of the capacitor 118 (the top surface of the second electrode 116). In this way, after the second dielectric layer 128 is formed, the second dielectric layer 128 on the contact 122 may have a larger thickness.

Afterwards, the steps described in FIGS. 4B and 4C may be performed to form the patterned conductive layer 126. At this time, the contact 122 may have a shorter length, and the connection portion 126b on the contact 122 may have a larger thickness.

In each of the above embodiments, as shown in FIGS. 2 and 5, the pattern portion 126a of the patterned conductive layer 126 has a plurality of openings 126c, one connection portion 126b is connected to the pattern portion 126a, and the openings 126c is filled or not filled by the second dielectric layer 128, but the present invention is not limited thereto. In other embodiments, the patterned conductive layer 126 may have other patterns, as long as the pattern portion located in the array region 100a may expose a part of the capacitor 118, the connection portion located in the peripheral region 100b is connected to the pattern portion, and the exposed capacitor 118 is not limited to being covered or not covered by the second dielectric layer 128.

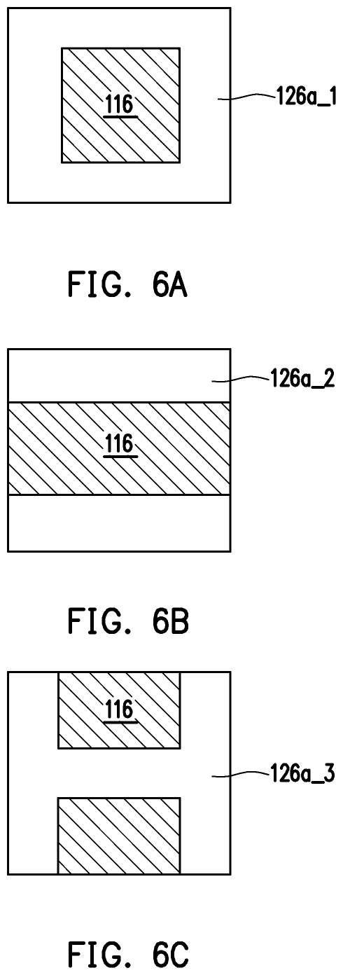

For example, as shown in FIG. 6A, the pattern portion 126a_1 of the patterned conductive layer 126 has only one opening exposing a part of the upper electrode (second electrode 116) of the capacitor 118. In addition, as shown in FIG. 6B, the pattern portion 126a_2 of the patterned conductive layer 126 includes two strips arranged in parallel, and the region between the two strips exposes a part of the upper electrode (second electrode 116) of the capacitor 118. In addition, as shown in FIG. 6C, in the pattern portion 126a_3 of the patterned conductive layer 126, the openings exposing a part of the upper electrode (second electrode 116) of the capacitor 118 is located at two opposite sides of the pattern portion 126a_3. In other embodiments, the upper electrode (second electrode 116) of the capacitor 118 exposed in FIGS. 6A to 6C is not limited to being covered or not covered by the second dielectric layer 128.

In each embodiment shown in FIGS. 6A to 6C, since the pattern portion of the patterned conductive layer 126 may expose a part of the upper electrode (second electrode 116) of the capacitor 118, during the H₂ sintering process, hydrogen may enter into the substrate 100 from the outside down through the gaps between the metal components via the regions not covered by the patterned conductive layer 126 to repair the dangling bonds.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate, comprising an array region and a peripheral region, wherein a transistor is disposed in the substrate in the array region and a conductive device is disposed in the substrate in the peripheral region;
a capacitor, disposed on the substrate and electrically connected to the transistor;
a patterned conductive layer, disposed on the capacitor and comprising a pattern portion and a connection portion connected to the pattern portion, wherein the pattern portion is located in the array region and exposes a part of the capacitor, and the connection portion is extended into the peripheral region; and
a contact, disposed on the substrate in the peripheral region and connecting the connection portion and the conductive device.

2. The semiconductor device of claim 1, wherein the capacitor comprises:
a first electrode, disposed on the substrate;
a second electrode, disposed on the first electrode; and
an insulating layer, disposed between the first electrode and the second electrode.

3. The semiconductor device of claim 2, wherein the top surface of the contact and the top surface of the second electrode are located at the same level.

4. The semiconductor device of claim 2, wherein the top surface of the contact is lower than the top surface of the second electrode.

5. The semiconductor device of claim 2, wherein a material of the second electrode comprises a doped semiconductor material.

6. The semiconductor device of claim 1, further comprising a first dielectric layer, wherein the capacitor and the contact are located in the first dielectric layer, and the top surface of the capacitor, the top surface of the contact and the top surface of the first dielectric layer are located at the same level.

7. The semiconductor device of claim 6, further comprising a second dielectric layer disposed on the capacitor and the first dielectric layer, wherein the patterned conductive layer is located in the second dielectric layer, and the top surface of the patterned conductive layer and the top surface of the second dielectric layer are located at the same level.

8. The semiconductor device of claim 1, further comprising a first dielectric layer, wherein the capacitor and the contact are located in the first dielectric layer, the top surface of the first dielectric layer is lower than the top surface of the capacitor, and the top surface of the contact and the top surface of the first dielectric layer are located at the same level.

9. The semiconductor device of claim 8, further comprising a second dielectric layer disposed on the capacitor and the first dielectric layer, wherein the patterned conductive layer is located in the second dielectric layer, and the top surface of the patterned conductive layer and the top surface of the second dielectric layer are located at the same level.

10. The semiconductor device of claim 1, wherein the pattern portion of the patterned conductive layer has a uniform width from the top surface to the bottom surface.

11. A manufacturing method of a semiconductor device, comprising:
providing a substrate, wherein the substrate comprises an array region and a peripheral region, a transistor is formed in the substrate in the array region, and a conductive device is formed in the substrate in the peripheral region;
forming a capacitor on the substrate in the array region, wherein the capacitor is electrically connected to the transistor;
forming a contact on the substrate in the peripheral region, wherein the contact is connected to the conductive device; and
forming a patterned conductive layer on the capacitor, wherein the patterned conductive layer comprises a pattern portion and a connection portion connected to the pattern portion, the pattern portion is located in the array region and exposes a part of the capacitor, and the connection portion is extended into the peripheral region to connect to the contact.

12. The method of claim 11, wherein after forming the capacitor and before forming the patterned conductive layer, the method further comprises:
forming a first dielectric layer on the substrate to cover the capacitor; and
performing a chemical mechanical polishing process to remove a part of the first dielectric layer until the top surface of the capacitor is exposed.

13. The method of claim 12, wherein after the chemical mechanical polishing process, the method further comprising performing an etching-back process to remove a part of the first dielectric layer, so that the top surface of the first dielectric layer is lower than the top surface of the capacitor.

14. The method of claim 12, wherein a forming method of the contact comprises:
forming a hole in the first dielectric layer in the peripheral region after the chemical mechanical polishing process, wherein the hole exposes a part of the conductive device; and
filling a conductive material in the hole.

15. The method of claim 11, wherein a forming method of the patterned conductive layer comprises:
forming a conductive material layer on the capacitor after forming the contact; and
performing a patterning process on the conductive material layer.

16. The method of claim 11, wherein a forming method of the patterned conductive layer comprises:
forming a second dielectric layer on the capacitor and the contact after forming the contact;
patterning the second dielectric layer to form trenches exposing a part of the capacitor and exposing the contact; and
filling a conductive material in the trenches.

17. The method of claim 11, further comprising performing an H₂ sintering process after the patterned conductive layer is formed.
